(19) United States
(12) Patent Application Publication
(10) Pub. No.: US 2026/0221948 A1
(43) Pub. Date: Jul. 30, 2026

(54) EFFICIENT TRAINING IN LINK REPEATER

(71) Applicant: Samsung Electronics Co., Ltd., Suwon-si (KR)

(72) Inventors: Karen SAHAKYAN, San Diego, CA (US); Joon-Young PARK, San Diego, CA (US)

(21) Appl. No.: 19/063,279

(22) Filed: Feb. 25, 2025

Related U.S. Application Data
(60) Provisional application No. 63/712,393, filed on Oct. 25, 2024.

(51) Int. Cl. H03F 3/19; H04L 25/03

(52) U.S. Cl. CPC H03F 3/19; H04L 25/03057; H03F 2200/451

(57) ABSTRACT

A system and a method for a repeater are described. The repeater includes a first amplifier and a second amplifier. The first amplifier is configured to be connected between a connection point in a decision feedback equalizer (DFE) and a first transmitter buffer to amplify a connection signal at the connection point. The second amplifier is configured to match the first amplifier and to be connected between a clock distribution circuit and a second transmitter buffer to amplify a distribution clock signal. The first transmitter buffer outputs a communication signal from the connection signal over a first link and the second transmitter buffer outputs a link clock signal from the distribution clock signal over the first link.

### CROSS-REFERENCE TO RELATED APPLICATION

This application claims the priority benefit under 35 U.S.C. § 119(e) of U.S. Provisional Patent Application Ser. No. 63/712,393 filed on Oct. 25, 2024, the disclosure of which is incorporated by reference in its entirety as if fully set forth herein.

### TECHNICAL FIELD

The disclosure generally relates to communication links in electronic circuits. More particularly, the subject matter disclosed herein relates to repeater in communication links.

### BACKGROUND

Signals in communication links travel on wires, cables, or other transmission media to carry data from one place to another. When traveling over a long distance, signals may become weakened or attenuated due to a variety of factors such as impedance mismatch, noise, crosstalk, interferences, obstructions, and reflection. To compensate for this diminished quality, repeaters are used to amplify and retransmit a weakened signal. Repeaters play an important role in maintaining signal integrity with respect to timings and signal strength.

Existing repeaters have a number of drawbacks. They require re-alignment before transmitting to the next stage. This re-alignment is part of a training process to match the retransmitted signal at the output of repeater because of retiming happens during equalization in repeater. This re-alignment is typically implemented by a timing circuitry involving a phase-locked loop, a finite state machine, and a delay lock loop. This re-alignment circuitry leads to increased silicon area and power consumption.

### SUMMARY

To overcome these issues, systems and methods are described herein for a technique of repeating a signal in a communication link. The repeater includes a first amplifier and a second amplifier. The first amplifier is configured to be connected between a connection point in a decision feedback equalizer (DFE) and a first transmitter buffer to amplify a connection signal at the connection point. The second amplifier is configured to match the first amplifier and to be connected between a clock distribution circuit and a second transmitter buffer to amplify a distribution clock signal. The first transmitter buffer outputs a communication signal from the connection signal over a first link and the second transmitter buffer outputs a link clock signal from the distribution clock signal over the first link.

### BRIEF DESCRIPTION OF THE DRAWINGS

In the following section, the aspects of the subject matter disclosed herein will be described with reference to exemplary embodiments illustrated in the figures, in which:

FIG. 1 is a block diagram illustrating a system according to an embodiment.

FIG. 2 is a diagram illustrating a repeater circuit according to an embodiment.

FIG. 3 is a diagram illustrating a linear equalizer according to an embodiment.

FIG. 4 is a diagram illustrating a decision feedback equalizer (DFE) according to an embodiment.

FIG. 5 is a diagram illustrating a transceiver amplifier and buffer circuit (TABC) according to an embodiment.

FIG. 6 is a flowchart illustrating a process of constructing a repeater according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The disclosure describes a communication technique using repeaters. The technique is efficient because it eliminates the need for re-aligning or retiming after equalization by using amplifiers and buffers at the link to the destination device. Equalization is still maintained to compensate for inter symbol interferences (ISI) and other losses. The benefits of the technique include: (1) reduced power consumption, (2) smaller area, (3) fast wake-up time, and (4) elimination of training between the repeater and the next device on the communication link.

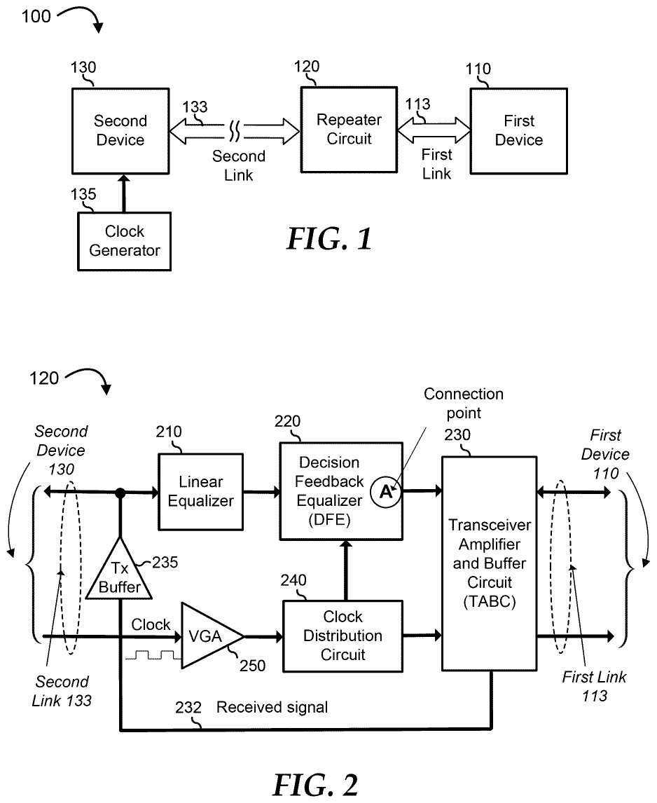

FIG. 1 is a block diagram illustrating a system 100 according to an embodiment. The system 100 represents an electronic circuit with communication links. A communication link typically includes a data signal and a clock signal. The system 100 includes a first device 110, a repeater circuit 120, a second device 130, and a clock generator 135. The system 100 may include more or less than these components.

The first device 110 may be any semiconductor device that uses a communication link to communicate with other devices. It may be a single device or a collection of devices in a system or subsystem. Examples of the first device 110 include a system on a chip (SoC), an integrated circuit (IC), an analog circuit, a digital circuit, an operational amplifier (Op-Amp), a timer, an audio amplifier, a video processor, a counter, an encoder, a memory circuit, a microprocessor, a microcontroller, a digital signal processor, a graphics processing unit (GPU), a central processing unit (CPU), a dynamic random access memory (DRAM), a double data rate (DDR) synchronous DRAM (e.g., DDR5, DDR6), a radio-frequency (RF) filter, an RF amplifier, an application-specific IC (ASIC), a sensor, a transducer, a Field Programmable Gate Array (FPGA), a communication interface circuit, a floating-point processor, and any device that uses a link or a connection for communication.

The repeater circuit 120 may perform a repeating function in an electronic system that uses a wired connectivity for communication. It may be a signal conditioning device that ensures a signal to maintain good quality when traveling from a source to a destination. It may be used in interconnections to transmit and receive data over communication channels connecting a device to another device. The data may be analog or digital. The repeater circuit 120 maintains the signal quality when facing distortions caused by factors such as impedance mismatch, noise, crosstalk, interferences, insertion losses, obstructions, and reflection. The repeater circuit 120 may amplify the signal, maintain synchronization between data and clock signals, or equalize the signal to compensate for any distortions caused by the communication channels, including ISI.

The second device 130 is similar to the first device 110. It may be a single device or a collection of devices in a system or subsystem. Like the first device 110, it may be any semiconductor device that uses a communication link to communicate with other devices. Examples of the second device 110 are similar to those of the first device 110 such as a SoC, an analog circuit, and a digital circuit.

The repeater circuit 120 is connected to the first device 110 via a wired connection, referred to as a first link 113. The first link 113 may be a high-speed serial link and includes a data signal and a clock signal. It may be bidirectional or unidirectional. The first link 113 may be a trace on a printed circuit board or a conductive wire that can carry electrical signals. Similarly, the repeater circuit 120 is connected to the second device 130 via a wired connection, referred to as a second link 133. The second link 133 may be high-speed serial link and includes a data signal and a clock signal. It may be a trace or a conductive wire. In one embodiment, the length of the second link 133 is longer than that of the first link 113. Since the second link 133 is long, the signal traveling from the second device 130 to the repeater circuit 120 receives more significant distortions, incurring more ISI distortions than the signal traveling from the repeater circuit 120 to the first device 110. Accordingly, the repeater circuit 120 has equalizers at the location where it is connected to the second link 133. The ISI is often characterized by a cursor, a precursor, and a post cursor. The cursor refers to the designated point in time within a signal where the main pulse of a transmitted symbol occurs, essentially acting as a reference point to identify the center of the symbol and differentiate between the pre-cursor (signals arriving before the main pulse) and post-cursor (signals arriving after the main pulse) ISI components. The repeater circuit 120 has equalizers that can compensate for pre-cursor and post-cursor ISI.

The clock generator 135 generates clock signals to the second device 130. The clock signals include a main clock signal that may be used to synchronize data signals. This main clock signal may be transmitted from the second device 130 to the repeater circuit 120 over the second link 133 and from the repeater circuit 120 to the first device 110 over the first link 113.

The timing relationship between the data signal and the clock signal in a communication link needs to be maintained throughout the link when traveling from one device to the next. Due to several loss factors such as insertion loss, interferences, or impedance mismatch, this timing relationship may be changed or impaired. Accordingly, to maintain this relationship, there is a training period during which the data signal and the clock signal are compared or synchronized. This training is done at every boundary between devices in a system. For the system 100 in FIG. 1, the training will be performed over the second link 133 at the input of the repeater circuit 120. Existing techniques also perform training over the first link 113 between the repeater circuit 120 and the first device 110. Existing techniques use timing circuits in the repeater circuit 120 at the outputs. This timing circuitry takes up space and area, consumes power, and requires training time. The technique in this disclosure replaces the timing circuitry with simple amplifiers and buffers and therefore eliminates the above problems.

FIG. 2 is a diagram illustrating the repeater circuit 120 shown in FIG. 1 according to an embodiment. The repeater circuit 120 includes a linear equalizer 210, a decision feedback equalizer (DFE) 220, a transceiver amplifier and buffer circuit (TABC) 230, a transmitter buffer 235, a clock distribution circuit 240, and a variable gain amplifier (VGA) 250. The repeater circuit 120 may include more or less than these components.

The linear equalizer 210 receives the data signal from the second link 133. It may boost the target frequency components of the signal. It is used to counteract the attenuation of target frequencies in communication channels, traces, or conductive wires by selectively amplifying high-frequency components in the signal. It may reduce both pre-cursors and post-cursors impact.

The DFE 220 may be a non-linear equalizer because it relies on the decisions made from previous symbols to refine the current symbol detection. It compensates for post-cursor ISI by utilizing past symbol decisions to effectively subtract the distortion caused by previously received symbols from the current symbol being detected. It essentially cleans up the signal by removing the post-cursor ISI that would otherwise interfere with the current bit interpretation. In one embodiment, this is achieved through a feedback loop that uses the previously detected bits to adjust the current signal based on their influence on the received waveform. The DFE 220 will be described with more details in FIG. 4.

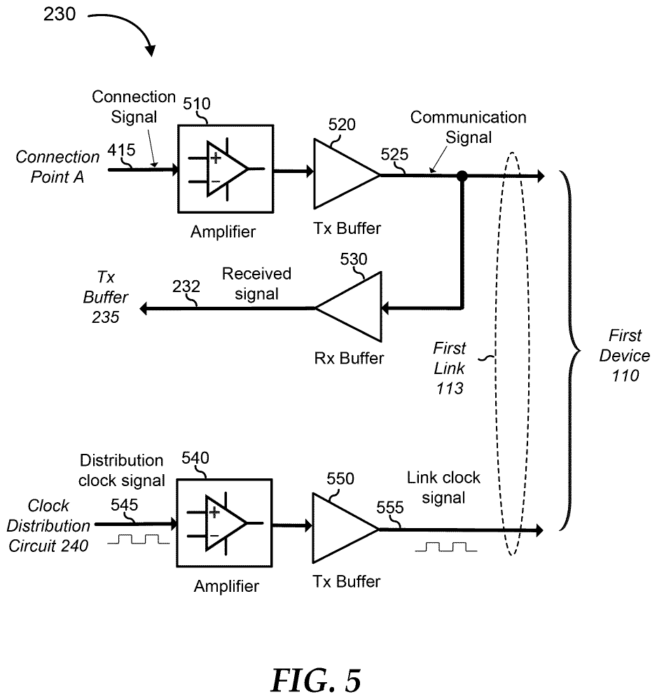

The TABC 230 amplifies and buffers signals from the DFE 220 and the clock distribution circuit 240. The TABC 230 replaces the timing and training circuits in traditional techniques. These timing and training circuits may include a phase-locked loop (PLL), a finite state machine, and a delay logic. By removing these circuits, the TABC 230 reduces hardware complexity, reduces silicon area and eliminates the training time at the post equalization stage. The TABC 230 generates a received signal 232 to the transmitter (Tx) buffer 235 which is connected to the second link 133. The TABC 230 will be described with more details in FIG. 5.

The VGA 250 receives a clock signal from the second link 133. It amplifies and strengthens the clock signal and provides the amplified clock signal to the clock distribution circuit 240. The clock distribution circuit 240 receives the clock signal from the second link 133 and repeats this clock signal to the first device 110. The clock distribution circuit 240 may include various timing circuitries such as counters, dividers, to generate various clock signals to be distributed to the DFE 220. It generates a distribution clock signal to the TABC 230.

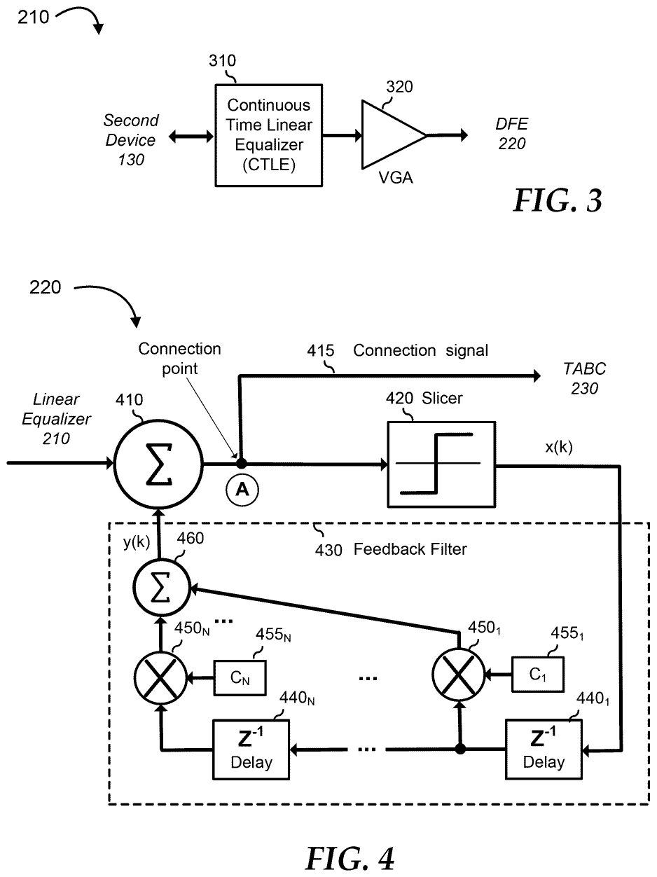

FIG. 3 is a diagram illustrating the linear equalizer 210 shown in FIG. 2 according to an embodiment. The linear equalizer 210 includes a continuous time linear equalizer (CTLE) 310 and a VGA 320. The linear equalizer 210 may include more or less than the above components.

The CTLE 310 equalizes the data signal from the second link 133. It operates on analog signals and produce analog results. In ideal situations, the CTLE 310 compensates for the communication channel loss. In other words, it provides the inverse of the channel's frequency response so that the result has a relatively flat magnitude. This effectively removes the precursor ISI and other distortions at high frequencies. The CTLE 310 may be implemented by incorporating resistive and capacitive degeneration in a differential pair.

The VGA 320 follows the CTLE 310 to amplify the signal to an appropriate value. It is an amplifier that varies its gain depending on a control signal such as a voltage. The output of the VGA 320 is connected to the DFE 220.

FIG. 4 is a diagram illustrating the DFE 220 shown in FIG. 2 according to an embodiment. The DFE 220 includes a summer 410, a slicer 420, and a feedback filter 430. The DFE 220 may include more or less than the above components.

The summer 410 subtracts the sum of the outputs of the feedback filter 430 from the output of the linear equalizer 210. In one embodiment, it is an analog summer. It may be implemented using a resistive load circuit or an integrating circuit. The output of the summer 410 is connected to the slicer 420 at a connection point A. The connection point A is the point where the TABC 230 is connected to the DFE 220. The signal from the connection point A to the TABC 230 may be referred to as a connection signal 415. This signal is the data signal that has been equalized by the linear equalizer 310 and is now equalized again by the DFE to effectively compensate for both pre-cursor and post-cursor ISI's.

The slicer 420 and the feedback filter 430 work together to perform equalization to reduce ISI. Since the second link 133 is often a long link and therefore has more losses and/or ISI, it is useful to keep the slicer 420 and the feedback filter 430 for ISI compensation. There may be several ways to implement the slicer 420 and the feedback filter 430, but the particular implementation does not affect the concept of using the TABC 230 to eliminate the retiming training by post-equalization circuitry. For purposes of illustration, the following is a description of the implementation of the slicer 420 and the feedback filter 430.

The slicer 420 is a hard-limiter that truncates the connection signal to two values by comparing the connection signal 415 with a threshold. In essence, it performs a decision on what the signal is at a time instant. The slicer 420 may have more than one hard-limiter arranged in cascade or in parallel. The output of the slicer 420 is x(k) and is connected to the feedback filter 430.

The feedback filter 430 performs the operation described by the following equation:

y(k)=Σⱼcⱼ*x[k−j] (j=1, . . . N) (1)
where y(k) is the output of the feedback filter 430 and x[k−j] is the delayed version of the output of the slicer 420.

The feedback filter 430 includes N delay elements 440j, N multipliers 450j, and N coefficients cⱼ 455ⱼ where j=1, . . . , N, and a summer 460. The multiplier 450ⱼ multiplies the delayed signal x[k−j]'s with the corresponding coefficients cⱼ's. The summer 460 adds all the outputs of the multipliers 450ⱼ's. The output of the summer 460 is y(k) and is subtracted from the summer 410,

FIG. 5 is a diagram illustrating the TABC 230 shown in FIG. 2 according to an embodiment. The TABC 230 effectively replaces the traditional re-alignment circuits and therefore eliminates the training period at this stage. The TABC 230 includes a first amplifier 510, a first transmitter (Tx) buffer 520, a Rx buffer 530, a second amplifier 540, and a second Tx buffer 550. The TABC 230 may include more or less than the above components.

The first amplifier 510 may be an operational amplifier (op-amp) that is configured to be connected between the connection point A shown in FIG. 4 in the DFE 220 and the first Tx buffer 520 to amplify the connection signal 415 at the connection point A. The first amplifier 510 operates in a rail-to-rail configuration. The first amplifier 510 and the first Tx buffer 520 form a data branch in the repeater circuit 120.

The Rx buffer 530 has an input connected to output of the first transmitter buffer 520 to receive a receive signal on the first link 113 and generate the received signal 232 that is sent to the Tx buffer 235 at the input of the linear equalizer 210 at the second link 133 as shown in FIG. 2. Depending on the configuration, one of the Rx buffer 530 and the Tx buffer 235 may be optional. This configuration allows for a bidirectional communication at the first link 113. If only a unidirectional configuration is needed from the repeater circuit 120 to the first device 110, the Rx buffer 530 and the Tx buffer 235 may not be needed.

The second amplifier 540 may also be an operational amplifier (op-amp) that is configured to match the first amplifier 510. It is connected between the clock distribution circuit 240 and the second Tx buffer 550 to amplify a distribution clock signal. The second amplifier 540 operates in a rail-to-rail configuration. The second amplifier 540 and the second Tx buffer 550 form a clock branch in the repeater circuit 120. The second amplifier 540 matches the first amplifier 510 based on at least one of size, input impedance, open-loop gain, offset voltage, and bandwidth. Since the two amplifiers are matched, their electrical and timing behaviors are almost identical. In addition, since they are simple circuits, they introduce very little delays. Accordingly, no training is needed to synchronize the clock signal and the data signal. The first Tx buffer 520 outputs a communication signal 525 from the connection signal 415 over the first link 113 and the second transmitter buffer 550 outputs a link clock signal 555 from the distribution clock signal 545 over the first link 113.

By taking the data signal directly after the summer 410 and allowing the data signal and the clock signal to go through the TABC 230 in two branches with similar timing characteristics, it is not necessary to have a training period at this location. Accordingly, the wake-up time, i.e., the time at power-on, is reduced because no training is needed at the side facing the first link 113. In addition to fast wake-up time, the TABC 230 also reduces area and power consumption because it employs simple circuits. Training may still be needed at the receiving side at the second link 133, but no training is required at the transmitting side at the first link 113. Accordingly, the TABC 230 provides a mechanism for efficient training in the repeater 120.

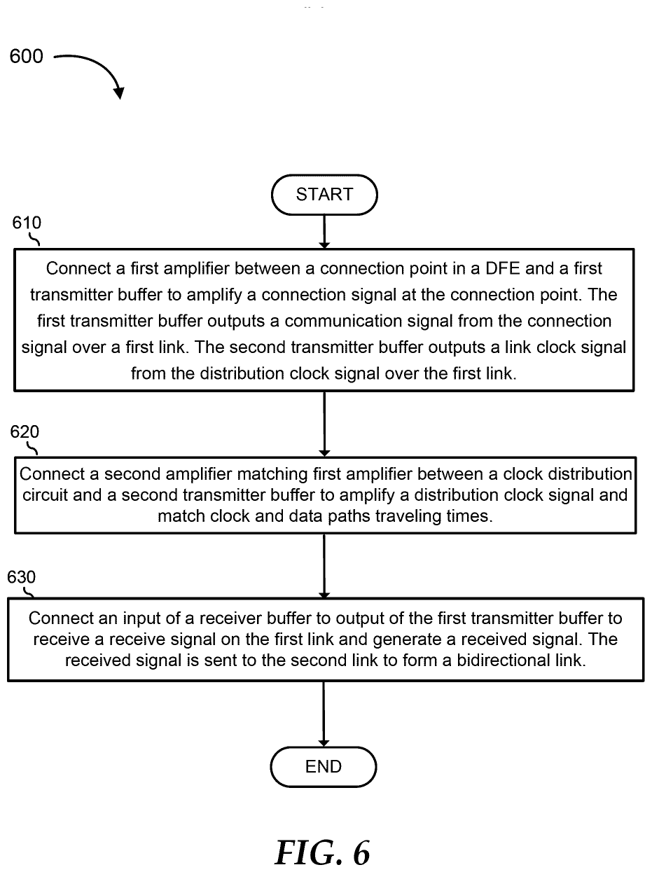

FIG. 6 is a flowchart illustrating a process 600 of constructing a repeater according to an embodiment.

Upon START, the process 600 connects a first amplifier between a connection point in a decision feedback equalizer (DFE) and a first transmitter buffer to amplify a connection signal at the connection point (Block 610). The first transmitter buffer outputs a communication signal from the connection signal over a first link. The second transmitter buffer outputs a link clock signal from the distribution clock signal over the first link. The DFE compensates for inter-symbol interference (ISI) by using a decision from the slicer to generate the connection signal from the summer that combines an output of a feedback filter and an output of a linear equalizer, The linear equalizer is placed at input of the DFE.

Next, the process 600 connects a second amplifier matching the first amplifier between the clock distribution circuit 240 and the second transmitter buffer 550 to amplify a distribution clock signal and match clock and data paths traveling times (Block 620).

Then, the process 600 connects an input of the receiver buffer 530 to output of the first transmitter buffer to receive a receive signal on the first link 113 and generate a received signal (Block 630). The first link 113 is therefore bidirectional. The received signal is sent to the second link. The second link is therefore also bidirectional. The process 600 is then terminated.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. An apparatus comprising:
a first amplifier configured to be connected between a connection point in a decision feedback equalizer (DFE) and a first transmitter buffer to amplify a connection signal at the connection point; and
a second amplifier configured to match the first amplifier and to be connected between a clock distribution circuit and a second transmitter buffer to amplify a distribution clock signal, and
wherein the first transmitter buffer outputs a communication signal from the connection signal over a first link and the second transmitter buffer outputs a link clock signal from the distribution clock signal over the first link.

2. The apparatus of claim 1, wherein the connection point is located between a summer and a slicer in the DFE.

3. The apparatus of claim 2, wherein the DFE compensates for inter-symbol interference (ISI) by using a decision from the slicer to generate the connection signal from the summer that combines an output of a feedback filter and an output of a linear equalizer,
wherein the linear equalizer is placed at input of the DFE.

4. The apparatus of claim 3, wherein the slicer is a hard-limiter to produce a binary data to the feedback filter.

5. The apparatus of claim 3, wherein the linear equalizer includes a continuous time linear equalizer to compensate for distortions caused by at least one of a channel loss and the ISI.

6. The apparatus of claim 3, further comprising:
a receiver buffer having an input connected to output of the first transmitter buffer to receive a receive signal on the first link and generate a received signal,
wherein the received signal is sent to input of the linear equalizer.

7. The apparatus of claim 6, wherein the input of the linear equalizer is connected to a second link.

8. The apparatus of claim 1, wherein the second amplifier matches the first amplifier based on at least one of size, input impedance, open-loop gain, offset voltage, and bandwidth.

9. The apparatus of claim 1, wherein the clock distribution circuit generate at least one of a synchronizing clock signal to the DFE and a distribution clock signal to the second amplifier.

10. The apparatus of claim 6, wherein the first link is connected to a first device and the second link is connected to a second device.

11. A method comprising:
connecting a first amplifier between a connection point in a decision feedback equalizer (DFE) and a first transmitter buffer to amplify a connection signal at the connection point; and
connecting a second amplifier matching the first amplifier between a clock distribution circuit and a second transmitter buffer to amplify a distribution clock signal, and
wherein the first transmitter buffer outputs a communication signal from the connection signal over a first link and the second transmitter buffer outputs a link clock signal from the distribution clock signal over the first link.

12. The method of claim 11, wherein the connection point is located between a summer and a slicer in the DFE.

13. The method of claim 12, wherein the DFE compensates for inter-symbol interference (ISI) by using a decision from the slicer to generate the connection signal from the summer that combines an output of a feedback filter and an output of a linear equalizer,
wherein the linear equalizer is placed at input of the DFE.

14. The method of claim 13, wherein the slicer is a hard-limiter to produce a binary data to the feedback filter.

15. The method of claim 13, wherein the linear equalizer includes a continuous time linear equalizer to compensate for distortions caused by at least one of a channel loss and the ISI.

16. The method of claim 13, further comprising:
connecting an input of a receiver buffer to output of the first transmitter buffer to receive a receive signal on the first link and generate a received signal,
wherein the received signal is sent to input of the linear equalizer.

17. The method of claim 16, wherein the input of the linear equalizer is connected to a second link.

18. The method of claim 11, wherein the second amplifier matches the first amplifier based on at least one of size, input impedance, open-loop gain, offset voltage, and bandwidth.

19. The method of claim 11, wherein the clock distribution circuit generate at least one of a synchronizing clock signal to the DFE and a distribution clock signal to the second amplifier.

20. A system comprising:
a first device;
a second device; and
a repeater circuit configured to be connected to the first device via a first link and to the second device via a second link, the repeater circuit comprising:
a first amplifier configured to be connected between a connection point in a decision feedback equalizer (DFE) and a first transmitter buffer to amplify a connection signal at the connection point; and
a second amplifier configured to match the first amplifier and to be connected between a clock distribution circuit and a second transmitter buffer to amplify a distribution clock signal, and
wherein the first transmitter buffer outputs a communication signal from the connection signal over the first link and the second transmitter buffer outputs a link clock signal from the distribution clock signal over the first link.
